(19) United States
(12) Patent Application Publication
(10) Pub. No.: US 2026/0329120 A1
(43) Pub. Date: Oct. 22, 2026

(54) DISPLAY DEVICE

(71) Applicant: LG ELECTRONICS INC., Seoul (KR)

(72) Inventor: Gihwan KIM, Seoul (KR)

(73) Assignee: LG ELECTRONICS INC., Seoul (KR)

(21) Appl. No.: 19/105,718

(22) PCT Filed: Jun. 27, 2023
(86) PCT No.: PCT/KR2023/008923

§ 371 Date: Feb. 21, 2025

(30) Foreign Application Priority Data
Aug. 22, 2022 (KR) 10-2022-0104827

(51) Int. Cl. G02F 1/1333; H05K 9/00

(52) U.S. Cl. CPC G02F 1/133314; G02F 1/133334; H05K 9/0054

(57) ABSTRACT

A display device is disclosed. The display device of the present disclosure may include: a display panel; a frame disposed at the rear of the display panel; a holder which is disposed at the rear of the frame and which is coupled to the frame; and a back cover which is coupled to the holder and which covers the rear of the frame, wherein the holder may include a base, which is in contact with the frame and which is coupled to the frame, and a contact portion, which is coupled to the base, which protrudes toward the rear of the base, and which is in contact with the inner surface of the back cover.

### TECHNICAL FIELD

The present disclosure relates to a display device.

### BACKGROUND ART

As the information society develops, the demand for display devices is also increasing in various forms. In response to this, various display devices such as Liquid Crystal Display Device (LCD), Plasma Display Panel (PDP), Electroluminescent Display (ELD), and Vacuum Fluorescent Display (VFD) have been researched and used in recent years.

Among them, a display device using an organic light emitting diode (OLED) has superior luminance characteristics and viewing angle characteristics compared to a liquid crystal display device, and can be implemented in an ultra-thin shape as it does not require a backlight unit.

Recently, research has been actively conducted to improve the assembly structure of display device while securing the rigidity of the display device.

In addition, research has been actively conducted to improve the Electro Magnetic Interference (EMI) contact structure to reduce EMI noise.

### DETAILED DESCRIPTION OF INVENTION

### Technical Problems

An object of the present disclosure is to solve the above-described problems and other problems.

Another object of the present disclosure may be to provide a coupling structure of a back cover with respect to a frame of a display device.

Another object of the present disclosure may be to provide a display device capable of sufficiently securing the rigidity of a holder to which a back cover is coupled.

Another object of the present disclosure may be to provide a display device capable of minimizing thermal deformation of a holder to which a back cover is coupled.

Another object of the present disclosure may be to provide a display device capable of preventing a back cover coupled to a holder from being separated from the holder.

Another object of the present disclosure may be to provide a display device capable of reducing Electro Magnetic Interference (EMI) noise.

Another object of the present disclosure may be to provide an EMI noise reduction structure between a holder and a back cover.

Another object of the present disclosure may be to provide an EMI noise reduction structure capable of improving EMI contact instability.

Another object of the present disclosure may be to provide an EMI noise reduction structure capable of increasing an EMI contact point.

### Technical Solution

According to an aspect of the present disclosure, there is provided a display device including: a display panel; a frame disposed at a rear of the display panel; a holder which is disposed at a rear of the frame and is coupled to the frame; and a back cover which is coupled to the holder and covers the rear of the frame, in which the holder includes: a base which is in contact with the frame and is coupled to the frame; and a contact part which is coupled to the base, protrudes toward a rear of the base, and is in contact with an inner surface of the back cover.

### Effect of Invention

The effects of the display device according to the present disclosure are described as follows.

According to at least one of the embodiments of the present disclosure, a coupling structure of a back cover with respect to a frame of a display device can be provided.

According to at least one of the embodiments of the present disclosure, a display device capable of sufficiently securing the rigidity of a holder to which a back cover is coupled can be provided.

According to at least one of the embodiments of the present disclosure, a display device capable of minimizing thermal deformation of a holder to which a back cover is coupled can be provided.

According to at least one of the embodiments of the present disclosure, a display device capable of preventing a back cover coupled to a holder from being separated from the holder can be provided.

According to at least one of the embodiments of the present disclosure, a display device capable of reducing Electro Magnetic Interference (EMI) noise can be provided.

According to at least one of the embodiments of the present disclosure, an EMI noise reduction structure between a holder and a back cover can be provided.

According to at least one of the embodiments of the present disclosure, an EMI noise reduction structure capable of improving EMI contact instability can be provided.

According to at least one of the embodiments of the present disclosure, an EMI noise reduction structure capable of increasing an EMI contact point can be provided.

Further scope of applicability of the present disclosure will become apparent from the following detailed description. However, it should be understood that the detailed description and specific embodiments such as preferred embodiments of the present disclosure are given by way of illustration only, since various changes and modifications within the spirit and scope of the present disclosure may be clearly understood by those skilled in the art.

### BRIEF DESCRIPTION OF THE DRAWING

FIGS. 1 to 21 are diagrams illustrating examples of a display device according to embodiments of the present disclosure.

### MODE FOR CARRYING OUT THE INVENTION

Description will now be given in detail according to exemplary embodiments disclosed herein, with reference to the accompanying drawings. For the sake of brief description with reference to the drawings, the same or equivalent components may be denoted by the same reference numbers, and description thereof will not be repeated.

In general, suffixes such as “module” and “unit” may be used to refer to elements or components. Use of such suffixes herein is merely intended to facilitate description of the specification, and the suffixes do not have any special meaning or function.

In the present disclosure, that which is well known to one of ordinary skill in the relevant art has generally been omitted for the sake of brevity. The accompanying drawings are used to assist in easy understanding of various technical features and it should be understood that the embodiments presented herein are not limited by the accompanying drawings. As such, the present disclosure should be construed to extend to any alterations, equivalents and substitutes in addition to those which are particularly set out in the accompanying drawings.

It will be understood that although the terms first, second, etc. may be used herein to describe various elements, these elements should not be limited by these terms. These terms are only used to distinguish one element from another.

It will be understood that when an element is referred to as being “connected with” another element, there may be intervening elements present. In contrast, it will be understood that when an element is referred to as being “directly connected with” another element, there are no intervening elements present.

A singular representation may include a plural representation unless context clearly indicates otherwise.

In the following description, even if the embodiment is described with reference to specific drawings, if necessary, reference numerals not appearing in the specific drawings may be referred to, and reference numerals not appearing in the specific drawings are used in a case where the above reference numerals appear in the other figures.

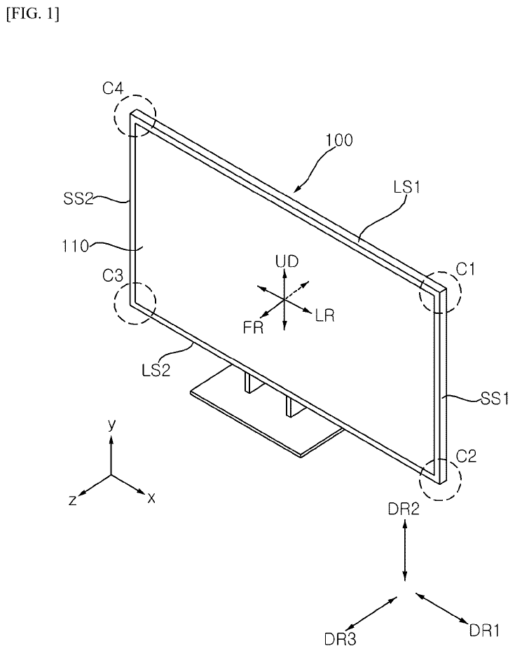

Referring to FIG. 1, a display device 100 may have a display panel 110. The display panel 110 may display an image. The display device 100 may include a first long side LS1, a second long side LS2 opposite to the first long side LS1, a first short side SS1 adjacent to the first long side LS1 and the second long side LS2, and a second short side SS2 opposite to the first short side SS1. Meanwhile, for the convenience of explanation, it is illustrated and described that the lengths of the first and second long sides LS1, LS2 are longer than the lengths of the first and second short sides SS1, SS2, but it may also be possible that the lengths of the first and second long sides LS1, LS2 are approximately equal to the lengths of the first and second short sides SS1, SS2.

The direction parallel to the long side LS1, LS2 of the display device 100 may be referred to as a first direction DR1 or a left-right direction LR. The direction parallel to the short side SS1, SS2 of the display device 100 may be referred to as a second direction DR2 or an up-down direction UD. The direction perpendicular to the long side LS1, LS2 and the short side SS1, SS2 of the display device 100 may be referred to as a third direction DR3 or a front-rear direction FR. Here, the direction in which the display panel 110 displays an image may be referred to as a front, and the opposite direction may be referred to as a rear.

The first long side LS1 side may be referred to as an upper side or an upper surface. The second long side LS2 side may be referred to as a lower side or a lower surface. The first short side SS1 side may be referred to as a left side or a left surface. The second short side SS2 side may be referred to as a right side or a right surface.

The first long side LS1, the second long side LS2, the first short side SS1, and the second short side SS2 may be referred to as an edge of the display device 100. In addition, a point where the first long side LS1, the second long side LS2, the first short side SS1, and the second short side SS2 meet each other may be referred to as a corner. For example, a point where the first long side LS1 and the first short side SS1 meet may be referred to as a first corner C1. A point where the first short side SS1 and the second long side LS2 meet may be referred to as a second corner C2. A point where the second long side LS2 and the second short side SS2 meet may be referred to as a third corner C3. A point where the second short side SS2 and the first long side LS1 meet may be referred to as a fourth corner C4.

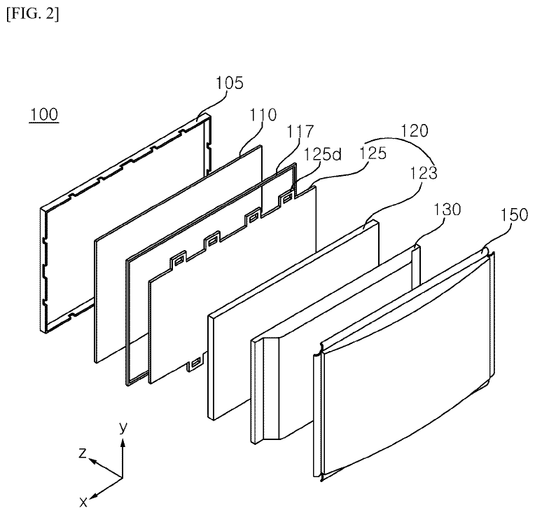

Hereinafter, the display device 100 having a display panel 110 as an LCD panel will be described as an example with reference to FIGS. 2 to 4, but the display device 100 according to the present disclosure may have various panels such as an OLED panel as the display panel 110.

Referring to FIG. 2, the display device 100 may include a front cover 105. The front cover 105 may cover at least a partial area of the front and side surfaces of the display panel 110. The front cover 105 may be divided into a front cover disposed on the front surface of the display panel 110 and a side cover disposed on the side surface. The front cover and the side cover may be configured separately. Either of the front cover and the side cover may be omitted.

The display device 100 may include a display panel 110. The display panel 110 may be a Liquid Crystal Display (LCD) panel. The display panel 110 is provided on the front surface of the display device 100 and may display an image. The display panel 110 may display an image by having a plurality of pixels output RGB Red, Green or Blue for each pixel in accordance with a timing. The display panel 110 can be divided into an active area where an image is displayed and a de-active area where an image is not displayed. The display panel 110 may include a front substrate and a rear substrate that are opposite to each other with a liquid crystal layer interposed therebetween.

The front substrate may include a plurality of pixels composed of red, green, and blue sub-pixels. The front substrate may output light corresponding to the color of red, green, or blue according to a control signal.

The rear substrate may include switching elements. The rear substrate may switch a pixel electrode. For example, the pixel electrode may change the molecular arrangement of the liquid crystal layer according to a control signal input from the outside. The liquid crystal layer may include liquid crystal molecules. The arrangement of the liquid crystal molecules may change in accordance with a voltage difference generated between the pixel electrode and the common electrode. The liquid crystal layer may transmit light provided from the backlight unit 120 to the front substrate or block it.

The display device 100 may include a guide panel 117. The guide panel 117 may be disposed behind the display panel 110. The guide panel 117 may support a portion of the rear surface of the display panel 110. The guide panel 117 may be in contact with an outer perimeter of the display panel 110. The guide panel 117 may be coupled to a frame 130 described below.

The display device 100 may include a backlight unit 120. The backlight unit 120 may be disposed behind the display panel 110. The backlight unit 120 may include light sources. The backlight unit 120 may be coupled to the frame 130 in front of the frame 130. The backlight unit 120 may be driven in a full driving method. The backlight unit 120 may be driven in a partial driving method. For example, the backlight unit 120 may be driven by a partial driving method such as local dimming, and impulsive. The backlight unit 120 may include an optical sheet 125 and an optical layer 123.

The optical sheet 125 may allow light from a light source to be evenly transmitted to the display panel 110. The optical sheet 125 may be composed of a plurality of layers. For example, the optical sheet 125 may include a prism sheet, a diffusion sheet, etc.

The optical sheet 125 may include a coupling portion 125d. The coupling portion 125d may be coupled to the front cover 105, the frame 130, and/or a back cover 150. The coupling portion 125d may be fastened to a structure formed or coupled to the front cover 105, the frame 130, and/or the back cover 150.

The display device 100 may include a frame 130. The frame 130 may be disposed behind the display panel 110. The frame 130 may support a partial configuration of the display device 100. For example, the backlight unit 120, a Printed Circuit Board (PCB) on which a plurality of electronic components are mounted, etc. may be coupled or fixed to the frame 130. The frame 130 may include a metal material. For example, the frame 130 may include a metal material such as stainless steel, aluminum alloy, and electro galvanized coil (EGI). The frame 130 may be called a main frame, an inner frame, or a module cover.

The display device 100 may include a back cover 150. The back cover 150 may form the rear surface of the display device 100. The back cover 150 may cover the rear of the frame 130. The back cover 150 may be coupled to the frame 130 and/or the front cover 105. For example, the back cover 150 may include a metal material.

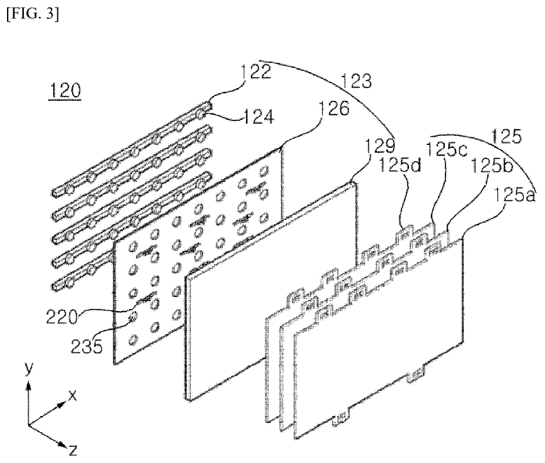

Referring to FIG. 3, the backlight unit 120 may include an optical layer 123. The optical layer 123 may include a substrate 122. The substrate 122 may extend in the left-right direction LR. The substrate 122 may be provided in the form of a strap. The substrate 122 may include a plurality of substrates 122. The plurality of substrates 122 may be spaced apart from each other in the up-down direction (UD). At least one optical assembly 124 may be mounted on the substrate 122. An electrode pattern for connecting the adapter and the optical assembly 124 may be formed on the substrate 122. For example, a carbon nanotube electrode pattern may be formed on the substrate 122 to connect the optical assembly 124 and the adapter. The substrate 122 may be composed of at least one of polyethylene terephthalate PET, glass, polycarbonate PC, and silicon. The substrate 122 may be a printed circuit board (PCB) on which at least one optical assembly 124 is mounted.

The optical layer 123 may include the optical assembly 124. The optical assembly 124 may be a light emitting diode (LED) chip. The optical assembly 124 may be a light emitting diode package including at least one light emitting diode chip. The optical assembly 124 may be composed of a colored LED that emits at least one color among colors such as red, green, and blue, or of a white LED. The colored LED may include at least one of a red LED, a green LED, and a blue LED.

The optical layer 123 may include a reflective sheet 126. The reflective sheet 126 may be disposed in front of the substrate 122. The reflective sheet 126 may include a through hole 235. An optical assembly 124 may be arranged in the through hole 235. The through hole 235 may include a plurality of through holes 235. The reflective sheet 126 may reflect light emitted from the optical assembly 124 or reflected from a diffusion plate 129 in a forward direction. The reflective sheet 126 may include a metal and/or metal oxide having a high reflectivity. For example, the reflective sheet 126 may include at least one of aluminum Al, silver Ag, gold Au, and titanium dioxide TiO2.

The optical layer 123 may include a diffusion plate 129. The diffusion plate 129 may be disposed in front of the reflective sheet 129. The diffusion plate 129 may be disposed between the reflective sheet 126 and the optical sheet 125.

An air gap may be formed between the reflective sheet 126 and the diffusion plate 129. The air gap may serve as a buffer to allow light emitted from the optical assembly 124 to be widely spread. A supporter 220 may be disposed between the reflective sheet 126 and the diffusion plate 129 to form the air gap.

The backlight unit 120 may include an optical sheet 125. The optical sheet 125 may be disposed in front of the optical layer 123. The optical sheet 125 may include at least one sheet. For example, the optical sheet 125 may include one or more prism sheets and/or one or more diffusion sheets. The plurality of sheets included in the optical sheet 125 may be in an adhered and/or closely attached state.

The optical sheet 125 may be composed of a plurality of sheets having different functions. For example, the optical sheet 125 may include a first optical sheet 125a, a second optical sheet 125b, and a third optical sheet 125c. For example, the first optical sheet 125a may be a diffusion sheet, and the second optical sheet 125b and the third optical sheet 125c may be a prism sheet. The number and/or positions of the diffusion sheets and the prism sheets may be changed. The diffusion sheet may prevent light emitted from the diffusion plate 129 from being partially concentrated, thereby making the light distribution more uniform. The prism sheet may collect light emitted from the diffusion plate 129 and provide it to the display panel 110.

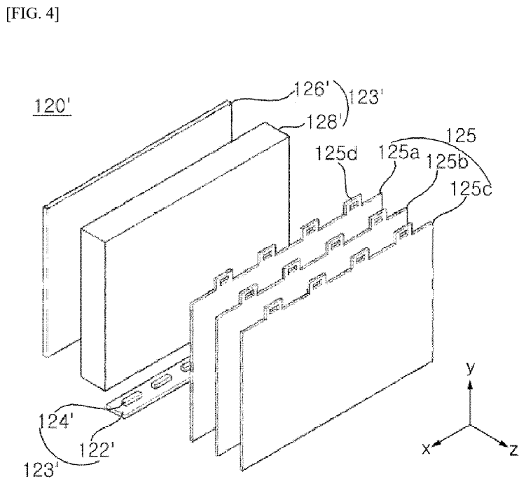

Referring to FIG. 4, the light source of a backlight unit 120′ may be arranged at the edge. A backlight unit 120′ may include an optical layer 123′ having a substrate 122′, at least one optical assembly 124′, a reflective sheet 126′, and a light guide plate 128′, and an optical sheet 125 disposed in front of the optical layer 123′.

The substrate 122′ may extend in the left-right direction LR and may be adjacent to the lower side of the light guide plate 128′. At least one optical assembly 124′ may be mounted on the substrate 122′. Accordingly, most of the light emitted from the optical assembly 124′ may be transmitted to the inside of the light guide plate 128′. Here, the light guide plate 128′ may reflect light incident from the optical assembly 124′ in a forward direction. For example, a diffusion plate 129′ may be provided on the front surface of the light guide plate 128′.

The reflection sheet 126′ may be disposed behind the light guide plate 128′. The reflection sheet 126′ may reflect light emitted from the optical assembly 124′ or reflected from the light guide plate 128′ in a forward direction.

An air gap may be formed between the light guide plate 128′ and the optical sheet 125. The air gap may serve as a buffer to allow light emitted from the optical assembly 124′ to be widely spread.

The optical sheet 125 may be disposed in front of the light guide plate 128′. The rear surface of the optical sheet 125 may be in close contact with the light guide plate 128′, and the front surface of the optical sheet 125 may be in close contact with the rear surface of the display panel 110.

The coupling portion 125d may be formed in at least one of the corners of the optical sheet 125. The coupling portion 125d may be formed at least one of the first optical sheet 125a, the second optical sheet 125b, and the third optical sheet 125c.

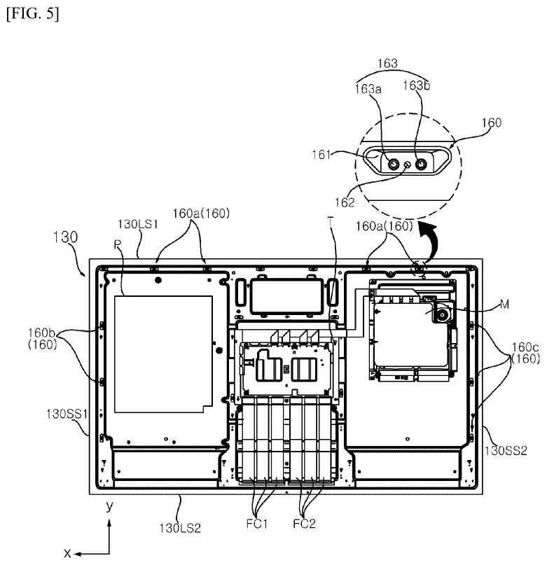

Referring to FIG. 5, a plurality of electronic components may be installed in the frame 130. The plurality of electronic components may be coupled or fixed to the rear surface of the frame 130. For example, the plurality of electronic components may include a power supply board P that provides power to each component of the display device 100, a timing controller board T that provides a video signal to the display panel 110 (see FIG. 1), and a main board M that controls each component of the display device 100. At this time, the timing controller board T may be connected to the display panel 110 via FFC cables FC1, FC2. The plurality of electronic components may be electrically connected to each other, or electrically connected to each component of the display device 100.

The frame 130 may be formed in a square plate shape. The upper side 130LS1 of the frame 130 may extend in the left-right direction LR. The lower side 130LS2 of the frame 130 may extend in the left-right direction LR. The lower side 130LS2 of the frame 130 may be opposite to the upper side 130LS1. The left side 130SS1 of the frame 130 may extend in the up-down direction UD. The left side 130SS1 of the frame 130 may connect the upper side 130LS1 and the lower side 130LS2. The right side 130SS2 of the frame 1300 may extend in the up-down direction UD. The right side 130SS2 may be opposite to the left side 130SS1. The right side 130SS2 may connect the upper side 130LS1 and the lower side 130LS2. The upper side 130LS1, the lower side 130LS2, the left side 130SS1, and the right side 130SS2 of the frame 130 may be referred to as an edge of the frame 130.

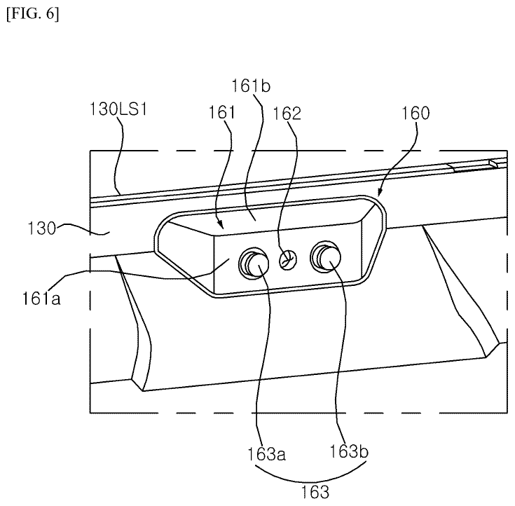

Referring to FIGS. 5 and 6, the frame 130 may include a recessed portion 160. The recessed portion 160 may be adjacent to the edge of the frame 130. The recessed portion 160 may include a plurality of recessed portions 160. The plurality of recessed portions 160 may be spaced apart from each other in the circumferential direction of the frame 130. The plurality of recessed portions 160 may be spaced apart from each other along the edge of the frame 130. For example, the plurality of recessed portions 160 may include at least one of a first recessed portion 160a, a second recessed portion 160b, and a third recessed portion 160c.

The first recessed portion 160a may be disposed adjacent to the upper side 130LS1 of the frame 130. The first recessed portion 160a may include a plurality of first recessed portions 160a. The plurality of first recessed portions 160a may be spaced apart from each other in the left-right direction LR along the upper side 130LS1.

The second recessed portion 160b may be disposed adjacent to the left side 130SS1 of the frame 130. The second recessed portion 160b may include a plurality of second recessed portions 160b. The plurality of second recessed portions 160b may be spaced apart from each other in the up-down direction UD along the left side 130SS1.

The third recessed portion 160c may be disposed adjacent to the right side 130SS2 of the frame 130. The third recessed portion 160c may include a plurality of third recessed portions 160c. The plurality of third recessed portions 160c may be spaced apart from each other in the up-down direction UD along the right side 130SS2. The third recessed portion 160c may overlap with the second recessed portion 160b in the left-right direction LR. The plurality of third recessed portions 160c may correspond one-to-one with the plurality of second recessed portions 160b.

The plurality of recessed portions 160 may further include a fourth recessed portion (not shown). The fourth recessed portion (not shown) may be disposed adjacent to the lower side 130LS2 of the frame 130. The fourth recessed portion (not shown) may include a plurality of fourth recessed portions (not shown). The plurality of fourth recessed portions (not shown) may be spaced apart from each other in the left-right direction LR along the lower side 130LS2. The fourth recessed portion (not shown) may overlap with the first recessed portion 160a in the up-down direction UD. The plurality of fourth recessed portions (not shown) may correspond one-to-one with the plurality of first recessed portions 160a.

The recessed portion 160 may include a body 161. The body 161 may be formed by recessing from the front surface of the frame 130 to the rear. The body 161 may include a first body 161a. The first body 161a may be disposed behind the front surface of the frame 130. The first body 161a may have a flat shape. The body 161 may include a second body 161b. The second body 161b may be disposed between the front surface of the frame 130 and the first body 161a. The second body 161b may connect the front surface of the frame 130 and the first body 161a. The second body 161b may extend inclinedly or vertically with respect to the front surface of the frame 130.

The recessed portion 160 may include a hole 162. The hole 162 may be formed by penetrating the body 161 in the front-rear direction FR. The hole 162 may be formed in the first body 161a. The hole 162 may be formed by penetrating the center of the first body 161a in the front-rear direction FR. The hole 162 may be disposed between a first protruding part 163a and a second protruding part 163b described below.

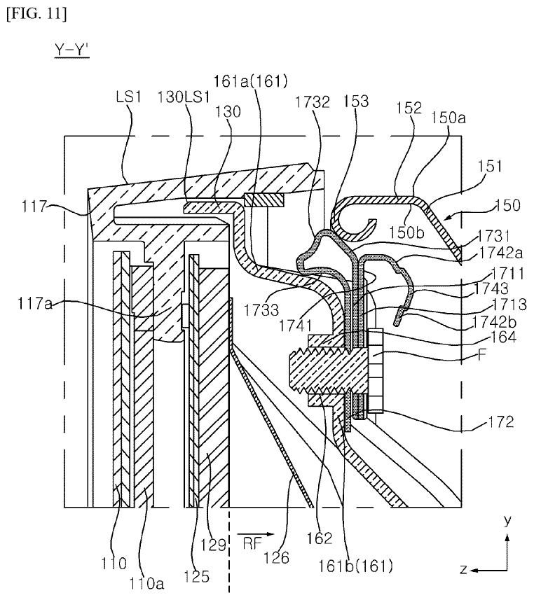

The recessed portion 164 may include a tapping part 164 (see FIG. 11). The tapping part 164 (see FIG. 11) may define the boundary of the hole 162. The tapping part 164 (see FIG. 11) may have screw threads formed on the inner circumferential surface.

The recessed portion 160 may include a protruding part 163. The protruding part 163 may protrude in a rearward direction from the rear surface of the body 161. The protruding part 163 may protrude in a rearward direction from the rear surface of the first body 161a. For example, the protruding part 163 may be formed in a solid cylinder shape. The protruding part 163 may include a plurality of protrusions 163. For example, the plurality of protrusions 163 may include a first protruding part 163a and a second protruding part 163b spaced apart from each other with a hole 162 interposed therebetween.

The first recessed portion 160a may include the first protruding part 163a and the second protruding part 163b spaced apart from each other in the left-right direction LR. The second recessed portion 160b may include the first protruding part 163a and the second protruding part 163b that are spaced apart from each other in the up-down direction UD. The third recessed portion 160c may include the first protruding part 163a and the second protruding part 163b that are spaced apart from each other in the up-down direction UD. The fourth recessed portion (not shown) may include the first protruding part 163a and the second protruding part 163b that are spaced apart from each other in the left-right direction LR.

Meanwhile, the recessed portion 160 may be referred to as a forming part 160, and the protruding part 163 may be referred to as an embo 163.

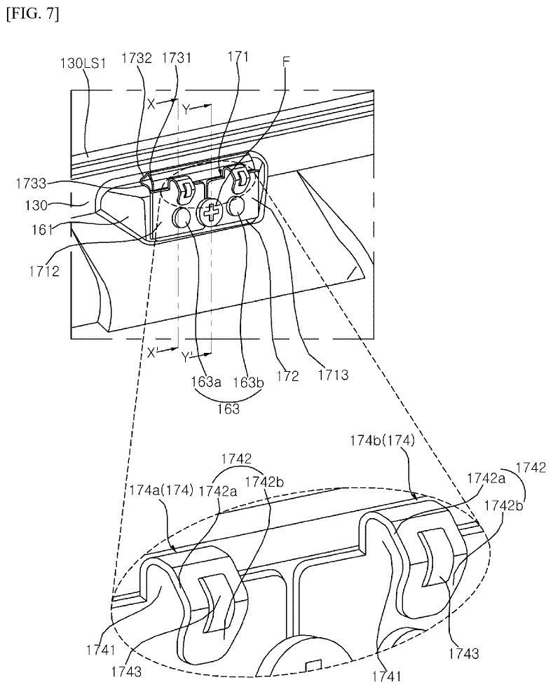

Referring to FIG. 7, the display device 100 may include a holder 170. The holder 170 may be referred to as a bracket or a mount. The holder 170 may be disposed behind the frame 130. The holder 170 may be coupled to the rear of the frame 130. The holder 170 may be coupled to the recessed portion 160. The holder 170 may be detachably coupled to the recessed portion 160.

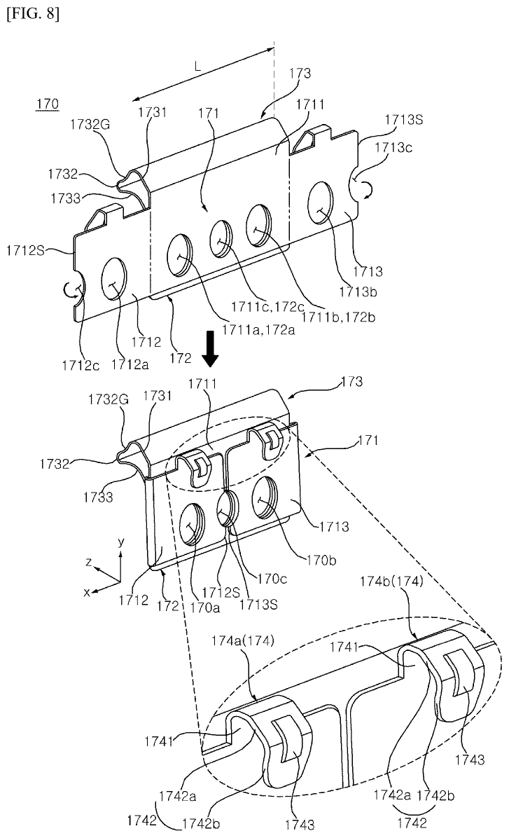

Referring to FIGS. 7 and 8, the holder 170 may include a base 171, 172. The base 171, 172 may be extended long. For example, when the holder 170 is coupled to the first recessed portion 160a and/or the fourth recessed portion (not shown), the longitudinal direction of the base 171, 172 may be parallel to the left-right direction LR (see FIG. 5). For example, when the holder 170 is coupled to the second recessed portion 160b and/or the third recessed portion 160c, the longitudinal direction of the base 171, 172 may be parallel to the up-down direction UD (see FIG. 5). The thickness direction of the base 171, 172 may be a direction intersecting with the longitudinal direction of the base 171, 172. For example, the thickness direction of the base 171, 172 may be parallel to the front-rear direction FR.

The base 171, 172 may include a second base 172. The second base 172 may be coupled to the first body 161a. The second base 172 may be coupled to the rear of the first body 161a. The second base 172 can be in contact with the rear surface of the first body 161a. The second base 172 may be extended long. The second base 172 may be a flat plate. The second base 172 may be formed in a shape corresponding to the first body 161a. For example, the second base 172 may be formed in a rectangular shape with a long side formed in the longitudinal direction of the base 172.

A first hole 172a may be formed in the second base 172. The first hole 172a of the second base 172 may be formed by penetrating the second base 172 in the front-rear direction FR. A second hole 172b may be formed in the second base 172. The second hole 172b of the second base 172 may be formed by penetrating the second base 172 in the front-rear direction FR. The second hole 172b of the second base 172 may be spaced apart from the first hole 172a of the second base 172 in the longitudinal direction of the second base 172. A third hole 172c may be formed in the second base 172. The third hole 172c of the second base 172 may be formed by penetrating the second base 172 in the front-rear direction FR. The third hole 172c of the second base 172 may be formed in the center of the second base 172. The third hole 172c of the second base 172 may be disposed between the first hole 172a and the second hole 172b of the second base 172. The first to third holes 172a, 172b, 172c of the second base 172 may be spaced apart from each other in the longitudinal direction of the second base 172.

The base 171, 172 may include a first base 171. The first base 171 may be disposed behind a second base 172, and may be in contact with the second base 172. That is, the first base 171 and the second base 172 may overlap with each other in the front-rear direction FR. The first base 171 may be in contact with the second base 172. The first base 171 may be opposite to the rear surface of the first body 161a with respect to the second base 172.

The first base 171 may include a center part 1711. The center part 1711 may be in contact with the second base 172 at the rear side of the second base 172. The center part 1711 may extend in the same direction as the longitudinal direction of the second base 172. The length of the center part 1711 in the longitudinal direction may be formed to be the same as the length of the second base 172 in the longitudinal direction. The center part 1711 may be formed in a shape corresponding to the second base 172. For example, the center part 1711 may be formed in a rectangular shape with a long side formed in the longitudinal direction of the center part 1711.

A first hole 1711a may be formed in the center part 1711. The first hole 1711a of the center part 1711 may be formed by penetrating the center part 1711 in the front-rear direction FR. The first hole 1711a of the center part 1711 may be aligned with the first hole 172a of the second base 172 in the front-rear direction FR. A second hole 1711b may be formed in the center part 1711. The second hole 1711b of the center part 1711 may be formed by penetrating the center part 1711 in the front-rear direction FR. The second hole 1711b of the center part 1711 may be aligned with the second hole 172c of the second base 172 in the front-rear direction FR. A third hole 1711c may be formed in the center part 1711. The third hole 1711c of the center part 1711 may be formed by penetrating the center part 1711 in the front-rear direction FR. The third hole 1711c of the center part 1711 may be formed in the center of the center part 1711. The third hole 1711c of the center part 1711 may be aligned with the third hole 172c of the second base 172 in the front-rear direction FR. The third hole 1711c of the center part 1711 may be disposed between the first hole 1711a and the second hole 1711b of the center part 1711. The first to third holes 1711a, 1711b, 1711c of the center part 1711 may be spaced apart from each other in the longitudinal direction of the center part 1711.

The first base 171 may include a first side part 1712. The first side part 1712 may extend from one side surface of the center part 1711. The first side part 1712 may extend in the longitudinal direction of the center part 1711 from one side surface of the center part 1711. The length of the first side part 1712 in the longitudinal direction may be less than the length of the center part 1711 in the longitudinal direction. For example, the length of the first side part 1712 may be less than or equal to half the length of the center part 1711.

The first side part 1712 may be folded toward the rear surface of the center part 1711. The first side part 1712 may be folded to come into contact with the rear surface of the center part 1711. A first hole 1712a may be formed in the first side part 1712. When the first side part 1712 is folded to the center part 1711, the first hole 1712a of the first side part 1712 may be aligned with the first hole 1711a of the center part 1711 in the front-rear direction FR. A third-first hole 1712c may be formed in the first side part 1712. The third-first hole 1712c may be formed by penetrating the first side part 1712 in the front-rear direction FR. The third-first hole 1712c may be formed by recessing from the side surface of the first side part 1712 toward the center part 1711. The third-first hole 1712c may be spaced apart from the first hole 1712a of the first side part 1712. The third-first hole 1712c may be formed in a semicircular shape. When the first side part 1712 is folded to the center part 1711, the third-first hole 1712c may be aligned with a part of the third hole 1711c of the center part 1711.

The first base 171 may include a second side part 1713. The second side part 1713 may extend from the other side surface located opposite to one side surface of the center part 1711. The second side part 1713 may extend in the longitudinal direction of the center part 1711 from the other side surface of the center part 1711. The length of the second side part 1713 in the longitudinal direction may be smaller than the length of the center part 1711 in the longitudinal direction. For example, the length of the second side part 1713 may be smaller than or equal to half the length of the center part 1711. The length of the second side part 1713 may be formed to be the same as the length of the first side part 1712.

The second side part 1713 may be folded toward the rear surface of the center part 1711. The second side part 1713 may be folded to come into contact with the rear surface of the center part 1711. A second hole 1713b may be formed in the second side part 1713. When the second side part 1713 is folded to the center part 1711, the second hole 1713b of the second side part 1713 may be aligned with the second hole 1711b of the center part 1711 in the front-rear direction FR. A third-second hole 1713c may be formed in the second side part 1713. The third-second hole 1713c may be formed by penetrating the second side part 1713 in the front-rear direction FR. The third-second hole 1713c may be formed by recessing from the side surface of the second side part 1713 toward the center part 1711. The third-second hole 1713c may be spaced apart from the second hole 1713b of the second side part 1713. The third-second hole 1713c may be formed in a semicircular shape. When the second side part 1713 is folded to the center part 1711, the third-second hole 1713c may be aligned with a part of the third hole 1711c of the center part 1711. When the first and second side parts 1712, 1713 are folded to the center part 1711, the third-first hole 1712c and the third-second hole 1713c may face each other in the longitudinal direction of the center part 1711 and may be combined to form a single hole.

The holder 170 may include a guide hole 170a, 170b. The number of guide holes 170a, 170b may be provided as many as the number of protruding part 163 (see FIG. 6). For example, the guide hole 170a, 170b may include a first guide hole 170a and a second guide hole 170b that are spaced apart from each other in the longitudinal direction of the base 171, 172 with a couling hole 170c interposed therebetween.

For example, the base 171, 172 may be coupled to the first recessed portion 160a and/or the fourth recessed portion (not shown) (see FIG. 5). In this case, the longitudinal direction of the base 171 may be parallel to the left-right direction LR, and the first guide hole 170a and the second guide hole 170b may be spaced apart from each other in the left-right direction LR. For example, the base 171, 172 may be coupled to the second recessed portion 160b and/or the third recessed portion 160c (see FIG. 5). In this case, the longitudinal direction of the base 171, 172 may be parallel to the up-down direction UD, and the first guide hole 170a and the second guide hole 170b may be spaced apart from each other in the up-down direction UD.

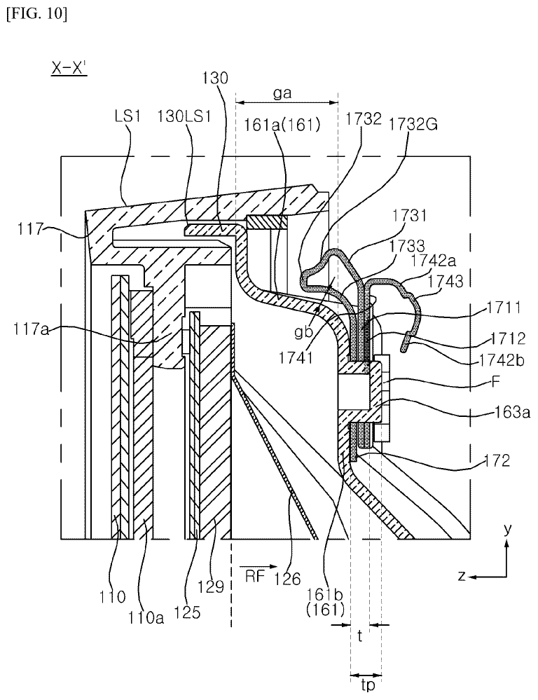

The first guide hole 170a may be formed by penetrating the base 171, 172 in the front-rear direction FR. The first guide hole 170a may be formed by combining the first hole 1711a of the center part 1711, the first hole 1712a of the first side part 1712, and the first hole 172a of the second base 172. A first protruding part 163a may be inserted into the first guide hole 170a. The depth of the first guide hole 170a in the front-rear direction FR may be smaller than the length of the first protruding part 163a in the front-rear direction FR. Accordingly, a portion of the first protruding part 163a may protrude from the rear surface of the base 171, 172 by a certain length tp (see FIG. 10).

The second guide hole 170b may be formed by penetrating the base 171, 172 in the front-rear direction FR. The second guide hole 170b may be formed by combining the second hole 1711b of the center part 1711, the second hole 1712b of the first side part 1712, and the second hole 172b of the second base 172. A second protruding part 163b may be inserted into the second guide hole 170b. The depth of the second guide hole 170b in the front-rear direction FR may be smaller than the length of the second protruding part 163b in the front-rear direction FR. Accordingly, a portion of the second protruding part 163b may protrude from the rear surface of the base 171, 172 by a certain length tp (see FIG. 10).

The holder 170 may include a coupling hole 170c. The coupling hole 170c may be formed by penetrating the base 171, 172 in the front-rear direction FR. The coupling hole 170c may be formed by combining the third hole 1711c of the center part 1711, the third-first hole 1712c of the first side part 1712, the third-second hole 1713c of the second side part 1713, and the third hole 172c of the second base 172. When the first protruding part 163a and the second protruding part 163b are inserted into the first guide hole 170a and the second guide hole 170b, the coupling hole 170c may be aligned with the hole 162 (see FIG. 6). Thus, the first protruding part 163a and the second protruding part 163b may guide the coupling of the holder 170 to the recessed portion 160. A fastening member F such as a screw may be inserted into the hole 162 through the coupling hole 170c and screw-fastened to the tapping part 164 (see FIG. 11). Thus, the holder 170 may be fixed to the recessed portion 160.

The holder 170 may include a bending part 173. The bending part 173 may be extended in the longitudinal direction of the base 171, 172. The length L of the bending part 173 may be equal to or smaller than the length of the base 171, 172. The bending part 173 may be fixed or coupled to one side of the base 171, 172. The bending part 173 may be bended multiple times. One end of the bending part 173 may be fixed or coupled to one side of the first base 171. The other end of the bending part 173 may be fixed or coupled to one side of the second base 172. At this time, one end and the other end of the bending part 173 may be adjacent or neighboring to each other. The inner surface of the bending part 173 may define the boundary of the space 173S. The space 173S may be extended in the longitudinal direction of the bending part 173.

When the base 171, 172 is coupled to the first recessed portion 160a, one end of the bending part 173 may be fixed to the upper surface of the first base 171, and the other end of the bending part 173 may be fixed to the upper surface of the second base 172. When the base 171, 172 is coupled to the fourth recessed portion (not shown), one end of the bending part 173 may be fixed to the lower surface of the first base 171, and the other end of the bending part 173 may be fixed to the lower surface of the second base 172. When the base 171, 172 is coupled to the second recessed portion 160b, one end of the bending part 173 may be fixed to the left side surface of the first base 171, and the other end of the bending part 173 may be fixed to the left side surface of the second base 172. When the base 171, 172 is coupled to the third recessed portion 160c, one end of the bending part 173 may be fixed to the right side surface of the first base 171, and the other end of the bending part 173 may be fixed to the right side surface of the second base 172.

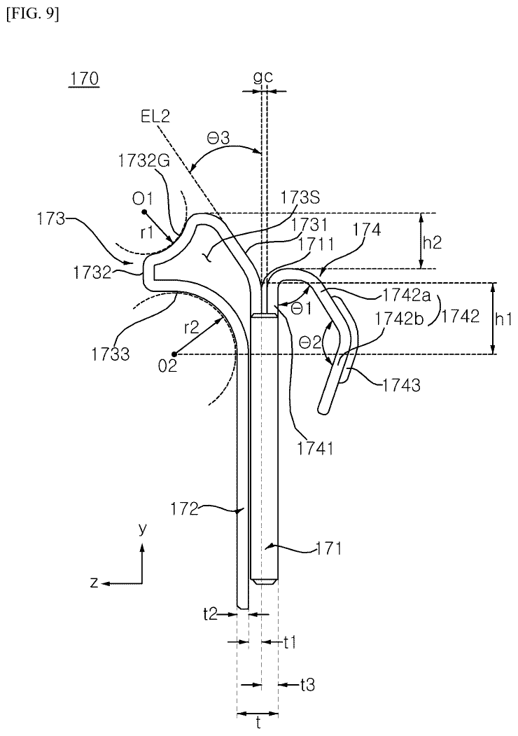

Referring to FIGS. 8 and 9, the bending part 173 may include a first tension portion 1731. The first tension portion 1731 may extend in a forward direction while forming a third angle (theta 3) from the first base 171 and may form one end of the aforementioned bending part 173. At this time, the third angle (theta 3) may be an acute angle. The first tension portion 1731 may be disposed behind a second tension portion 1733 described below. For example, the first tension portion 1731 may be formed flat.

The bending part 173 may include a seating portion 1732. The seating portion 1732 may extend in a forward direction while rolling from the first tension portion 1731. The seating portion 1732 may be disposed between the first tension portion 1731 and a second tension portion 1733 described below, and may connect the first tension portion 1731 and the second tension portion 1733. The seating portion 1732 may be extended in the longitudinal direction of the bending part 173. The seating portion 1732 may include a groove 1732G formed to be curved. The groove 1732G may be formed by recessing from the outer surface of the seating portion 1732 toward the space 173S or the base 171, 172. The groove 1732G may be extended while drawing an arc of a first radius r1 with respect to a first center O1 located on the outer side of the space 173S. That is, the groove 1732G may be formed concavely toward the space 170S.

The bending part 173 may include a second tension portion 1733. The second tension portion 1733 may be disposed in front of the first tension portion 1731. The second tension portion 1733 may face the frame 130. The second tension portion 1733 may be spaced rearward from the frame 130. The second tension portion 1733 may extend while rolling from the seating portion 1732 toward the rear or the base 171, 172. The second tension portion 1733 may form the other end of the bending part 173. The second tension portion 1733 may be extended while drawing an arc of a second radius r2 with respect to a second center 02 located on the outside of the space 173S. The second tension portion 1733 may be formed concavely toward the space 173S or the base 171, 172.

One end of the bending part 173 may be formed at the distal end of the first tension portion 1731, and the other end of the bending part 173 may be formed at the distal end of the second tension portion 1733. One end of the bending part 173 formed in the first tension portion 1731 and the other end of the bending part 173 formed in the second tension portion 1732 may be spaced apart from each other by a certain distance h1 in a direction intersecting with the longitudinal direction of the bending part 171, 172. For example, when the base 171, 172 is coupled to the first recessed portion 160a, the distal end of the second tension portion 1733 may be spaced downward by a certain distance h1 from the distal end of the first tension portion 1731. For example, when the base 171, 172 is coupled to the fourth recessed portion (not shown), the distal end of the second tension portion 1733 may be spaced upward by a certain distance hl from the distal end of the first tension portion 1731. For example, when the base 171, 172 is coupled to the second recessed portion 160b, the distal end of the second tension portion 1733 may be spaced to the right compared to the distal end of the first tension portion 1731. For example, when the base 171, 172 is coupled to the third recessed portion 160c, the distal end of the second tension portion 1733 may be spaced to the left compared to the distal end of the first tension portion 1731.

Through this, a part of the first base 171, the inner surfaces of the first tension portion 1731, the seating portion 1732, and the second tension portion 1733 may define the boundary of the space 173S. As one end and the other end of the bending part 173 are fixed to the base 171, 172, an external force or stress applied to the bending part 173 may be distributed to the bending part 173 and the base 171, 172.

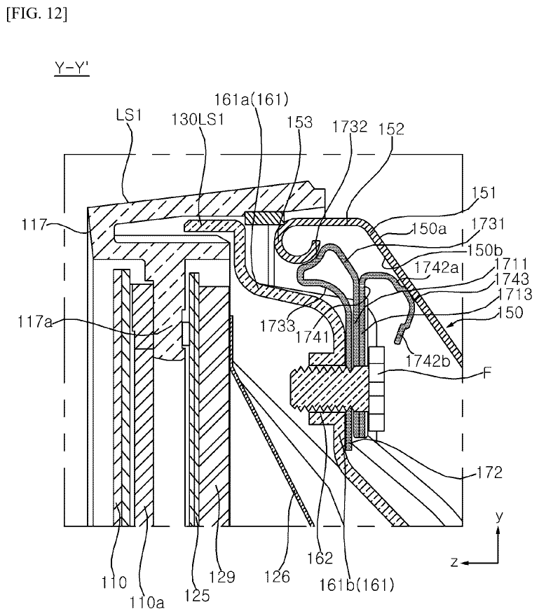

The holder 170 can include a contact part 174. The contact part 174 may be coupled to the base 171, 172. The contact part 174 may extend in a rearward direction from the base 171, 172. For example, the contact part 174 may extend horizontally in a rearward direction from one side of the base 171, 172. For example, the contact part 174 may extend while being bent in a rearward direction from one side of the base 171, 172. The contact part 174 may be in contact with the inner surface 150b of the back cover 150 (see FIG. 12).

The contact part 174 may include a support portion 1741. The support portion 1741 may extend from one side of the base 171, 172 in a direction perpendicular to the longitudinal direction of the base 171, 172 and the thickness direction of the base 171, 172. The thickness direction of the base 171, 172 may be parallel to the front-rear direction FR. For example, when the base 171, 172 is coupled to the first recessed portion 160a, the support portion 1741 may extend upward from the upper surface of the base 171, 172. For example, when the base 171, 172 is coupled to the fourth recessed portion (not shown), the support portion 1741 may extend downward from the lower surface of the base 171, 172. For example, when the base 171, 172 is coupled to the second recessed portion 160b, the support portion 1741 may extend to the left from the left surface of the base 171, 172. For example, when the base 171, 172 is coupled to the third recessed portion 160c, the support portion 1741 may extend from the right surface of the base 171, 172 to the right.

The support portion 1741 may extend from the side part 1712, 1713 in a direction perpendicular to the longitudinal direction of the base 171, 172 and the thickness direction of the base 171, 172. Alternatively, the support portion 1741 may extend from the center part 1711 in a direction perpendicular to the longitudinal direction of the base 171, 172 and the thickness direction of the base 171, 172.

The contact part 174 may include an elastic portion 1742. The elastic portion 1742 may extend in a rearward direction from the support portion 1741. The elastic portion 1742 may extend while being bent in a rearward direction from the support portion 1741. The elastic portion 1742 may be bent in a direction opposite to the direction in which the bending part 173 is bent. The elastic portion 1742 may face the rear surface of the base 171, 172. The elastic portion 1742 may face the side part 1712, 1713. At least a portion of the elastic portion 1742 may be in contact with the inner surface 150b of the back cover 150 (see FIG. 12). The elastic portion 1742 may be spaced in a rearward direction from the rear surface of the base 171, 172. A space may be formed between the elastic portion 1742 and the rear surface of the base 171, 172. Through this, when the back cover 150 is coupled to the holder 170, the elastic portion 1742 may be elastically deformed in a forward direction by the back cover 150, and may be restored in a rearward direction by the restoring force of the elastic portion 1742 to come into contact with the inner surface 150b of the back cover 150.

The elastic portion 1742 may include a first part 1742a. The first part 1742a may extend from the support portion 1741. The first part 1742a may be bent in a rearward direction from the support portion 1741. The first part 1742a may be bent from the support portion 1741 and may extend toward the back cover 150. The first part 1742a may be spaced in a rearward direction from the rear surface of the base 171, 172. For example, the first part 1742a may extend obliquely with respect to the rear surface of the base 171, 172. The distance between the first part 1742a and the rear surface of the base 171, 172 may increase as it moves away from the support 1741. The first part 1742a may be in contact with the inner surface 150b of a cover portion 151 (see FIG. 12). The first part 1742a may extend parallel to the cover portion 151 of the back cover 150 (see FIG. 12). Through this, the contact area between the first part 1742a and the inner surface 150b of the back cover 150 may increase. Through this, the contact part 174 may stably be in contact with the back cover 150, and reduce Electro Magnetic Interference (EMI) noise. For example, the first part 1742a may include a flat surface.

The elastic portion 1742 may include a second part 1742b. The second part 1742b may extend from the first part 1742a. The second part 1742b may extend while bending from the first part 1742a. The second part 1742b may be bent from the first part 1742a toward the base 171, 172. The second part 1742b may face the rear surface of the base 171, 172. The second part 1742b may be spaced in a rearward direction from the rear surface of the base 171, 172. The second part 1742b may get closer to the rear surface of the base 171, 172 as it gets farther away from the first part 1741a. The distance between the second part 1742b and the rear surface of the base 171, 172 may decrease as it gets farther away from the first part 1741a. For example, the second part 1742b may include a flat surface. At least a portion of the second part 1742b may be in contact with the inner surface 150b of the back cover 150. The second part 1742b may come into contact with the inner surface 150b of the back cover 150, if the elastic portion 1742 is pressed by the back cover 150 when the back cover 150 is coupled to the holder 170.

The first part 1741a may be bent to form a first angle (theta 1) from the support portion 1741. The second part 1741b may be bent to form a second angle (theta 2) from the first part 1741a. The first angle (theta 1) may be smaller than the second angle (theta 2). For example, the first angle (theta 1) may be an acute angle, and the second angle (theta 2) may be an obtuse angle. As the second angle (theta 2) is formed to be larger than the first angle (theta 1), if the elastic portion 1742 is pressed by the back cover 150, the elastic portion 174 may be elastically deformed. In addition, as the first angle (theta 1) is formed to be smaller than the second angle (theta 2), the support portion 1741 may strongly support the elastically deformed elastic portion 1744 and may be restored by the restoring force.

In the above, it is illustrated and described that the elastic portion 1742 is extended and bent from the support portion 1741, but it is not limited thereto. For example, the elastic portion 1742 may be extended while being bent rearward from one side of the base 171, 172, and in this case, the support portion 1741 may be omitted.

The contact part 174 may include a protrusion 1743. The protrusion 1743 may protrude in a rearward direction from the elastic portion 1742. The protrusion 1743 may be formed on the first part 1742a of the elastic portion 1742. The protrusion 1743 may be formed on the second part 1742b of the elastic portion 1742. The protrusion 1743 may be in contact with the inner surface 150b of the back cover 150 (see FIG. 12). Through this, the contact part 174 and the back cover 150 may be easily contacted, and EMI noise may be reduced.

The contact part 174 may include a plurality of contact parts 174. Through this, a contact point between the contact part 174 and the back cover 150 may be increased. Through this, the contact failure of the contact part 174 and the back cover 150 may be improved, and EMI noise may be reduced. The plurality of contact parts 174 may be spaced apart from each other. The plurality of contact parts 174 may be spaced apart in the longitudinal direction of the base 171, 172. For example, the plurality of contact parts 174 may include a first contact part 174a and a second contact part 174b. The first contact part 174a may be fixed to the first site part 1712. The second contact part 174a may be fixed to the second site part 1713.

The thickness t of the base 171, 172 in the front-rear direction FR may be the sum of the thickness t1, t3 of the first base 171 and the thickness t2 of the second base 172. The first side part 1712 and the second side part 1713 may form the first base 171 together with the center part 1711. The first side part 1712 and the second side part 1713 may have the same thickness t3. The thickness t1, t3 of the first base 171 may be the sum of the thickness t1 of the center part 1711 and the thickness t3 of the side part 1712, 1713. Through this, the torsional rigidity and/or the bending rigidity of the base 171, 172 may be improved.

Referring to FIG. 10, the holder 170 may be coupled to the frame 130 at the rear of the frame 130. Here, FIG. 10 is a cross-section taken along the line X-X′ of FIG. 7. The holder 170 may be detachably coupled to the recessed portion 160. The first protruding part 163a may be inserted into the first guide hole 170a (see FIG. 8), and the second protruding part 163b may be inserted into the second guide hole 170b (see FIG. 8). At this time, the first protruding part 163a may protrude from the rear surface of the body 161 by a certain length tp. Here, the certain length tp may be the same as the length by which the second protruding part 163b protrudes from the rear surface of the body 161, and may be greater than the thickness t of the base 171, 172. Thus, the first protruding part 163a and the second protruding part 163b may stably support the holder 170 into which they are inserted.

The guide panel 117 may form a side surface of the display device 100. The rib 117a may protrude from the guide panel 117 toward the inside of the display device 100. A foam pad 110a may be coupled to the display panel 110 and the rib 117a at between the display panel 110 and the rib 117a. The optical sheet 125 and the diffusion plate 129 may be opposite to the foam pad 110a with respect to the rib 117a.

The portion forming the outer perimeter of the frame 130 may be inserted into the guide panel 117. The frame 130 may be fixed to the guide panel 117.

The rim (not shown) of the reflective sheet 126 may be in contact with the rear surface of the diffusion plate 129, and the remaining portion of the reflective sheet 126 may extend obliquely in a rearward direction from the rim (see RF of 10). In this case, the front surface of the first body 161a may be spaced in a rearward direction from the front surface of the frame 130 by a certain distance ga. Accordingly, the fastening member F fastened to the tapping part 164 may not interfere with or be in contact with the reflective sheet 126.

The second base 172 may be located at the rear surface of the first body 161a and may be in contact with the first body 161a. The second tension portion 1733 may be located at the rear surface of the second body 161b, and may be spaced in a rearward direction from the second body 161b by a certain distance gb. Accordingly, the first tension portion 1731 and the second tension portion 1733 may be elastically deformed toward the second body 161b according to the external force, or may be restored to an original position, that is, a position where the second tension portion 1733 is spaced from the second body 161B by a certain distance gb, according to the elastic force.

Referring to FIGS. 11 and 12, the back cover 150 may be located at the rear of the frame 130, and may cover the rear of the frame 130. Here, FIGS. 11 and 12 are a cross-section taken along the Y-Y′ line of FIG. 7. The back cover 150 may include a cover portion 151, a connecting portion 152, and a coupling portion 153.

The cover portion 151 may form the rear surface of the back cover 150. The cover portion 151 may cover the recessed portion 160 and the rear of the holder 170. The cover portion 151 may be formed flat or inclined with respect to the frame 130. The connecting portion 152 may form a side surface of the back cover 150. The connecting portion 152 may be bent from the cover portion 151 and extended toward the frame 130. The angle between the connecting portion 152 and the cover portion 151 may be an obtuse angle. For example, the connecting portion 152 may be extended parallel in the front-rear direction. The connecting portion 153 may be curled from the distal end of the connecting portion 152 toward the inner surface of the connecting portion 152. Meanwhile, the connecting portion 153 may be referred to as a locking portion or a hook.

The back cover 150 may be detachably coupled to the holder 170. Specifically, when a user assembles the back cover 150 to the holder 170, the coupling portion 153 may be guided along the first tension portion 1731 to the seating portion 1732. At this time, the force applied by a user is transmitted to the first tension portion 1731 through the coupling portion 153, so that the first tension portion 1731 and the second tension portion 1732 may be elastically deformed in the counterclockwise direction. Thus, the coupling portion 153 may be fixed or coupled to the seating portion 1732 beyond the first tension portion 1731. At this time, the contact length of the coupling portion 153 and the seating portion 1732 may be L (see FIG. 8). In addition, the curvature of the coupling portion 153 may be the same as the curvature of the seating portion 1732.

The contact part 174 may be disposed at a position spaced apart from the bending part 173 in the direction toward the base 171, 172 (see ‘h2’ of FIG. 9). For example, when the base 171, 172 is coupled to the first recessed portion 160a, the contact part 174 may be spaced apart downward from the bending part 173. For example, when the base 171, 172 is coupled to the fourth recessed portion (not shown), the contact part 174 may be spaced apart upward from the bending part 173. For example, when the base 171, 172 is coupled to the second recessed portion 160b, the contact part 174 may be spaced to the right from the bending part 173. For example, when the base 171, 172 is coupled to the third recessed portion 160c, the contact part 174 may be spaced to the left from the bending part 173. Through this, collision and/or interference between the coupling portion 153 and the contact part 174 may be prevented during the process in which the coupling portion 153 is guided to the seating portion 1732 along the first tension portion 1731.

Meanwhile, the frame 130, the recessed portion 160, the holder 170, the fastening member F, and the back cover 150 may include an electrically conductive material such as metal. Accordingly, the Electro Magnetic Interference (EMI) noise of the plurality of electronic components installed in the frame 130 may be reduced. In addition, as the recessed portion 160 and the holder 170 include a metal material, the thermal deformation of these components may be minimized compared to a case of including materials such as plastic and synthetic resin.

Meanwhile, a painted layer formed by coating an insulating material (not shown) may be formed on the outer surface 150a of the back cover 150. The inner surface 150b of the back cover 150 may not be coated with an insulating material, and thus an exposed surface 150b where a conductive material is exposed may be formed. In this case, the insulating material coated on the outer surface of the coupling portion 153 may fall off during the process in which the coupling portion 153 slides on the first tension portion 1731 and is seated on the seating portion 1732. Accordingly, electricity may be transmitted from the recessed portion 160 to the coupling portion 153 through the uncoated portion of the insulating material of the coupling portion 153. Accordingly, while insulating the outer surface of the back cover 150, Electro Magnetic Interference (EMI) noise of a plurality of electronic components installed in the frame 130 may be reduced.

When the coupling portion 153 of the back cover 150 is guided through the first tension portion 1731 and is seated on the seating portion 1732 of the holder 170, the cover portion 151 of the back cover 150 may come into contact with the elastic portion 1742 of the contact part 174 and press the contact part 174 in a forward direction. When pressed by the cover portion 151, the elastic portion 1742 may be elastically deformed in a forward direction. When the coupling portion 153 is seated on the seating portion 1732, the elastic portion 1742 may be restored to the rear by the restoring force. At this time, the elastic portion 1742 may be in contact with the inner surface 150b of the back cover 150. The insulating material coating of the coupling portion 153 may not be removed or may be partially removed during the process of moving along the first tension portion 1731. In this case, even if the coupling portion 153 and the seating portion 1732 are in contact, EMI noise reduction may not be possible due to poor contact. Accordingly, the poor contact between the holder 170 may be improved and EMI noise may be reduced, through contact between the contact part 174 and the inner surface 150b of the back cover 150 that is not coated with the insulating material, in addition to the contact between the coupling portion 153 and the seating portion 1732. In addition, the contact part 174 may be in contact with the back cover 150 to fix the back cover 150, thereby preventing the detaching of the back cover 150 due to the tension structure of the bending part 173.

The contact part 174 may be spaced in a rearward direction from the first tension portion 1731 by a certain distance gc (see FIG. 9). The support portion 1741 of the contact part 174 may be spaced in a rearward direction from the first tension portion 1731 by a certain distance gc (see FIG. 9). Through this, when the contact part 174 is pressed by the back cover 150, an elastic deformation space in the front-rear direction of the contact part 174 may be secured.

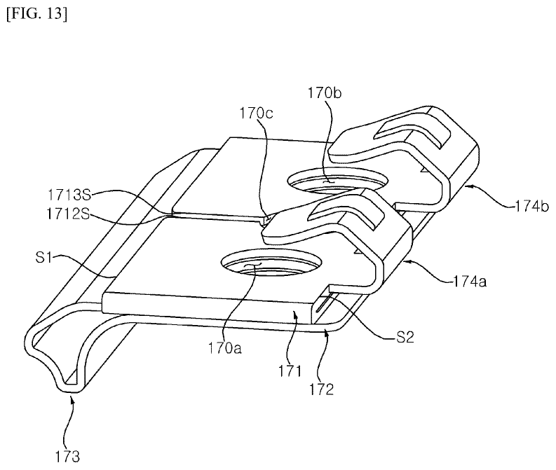

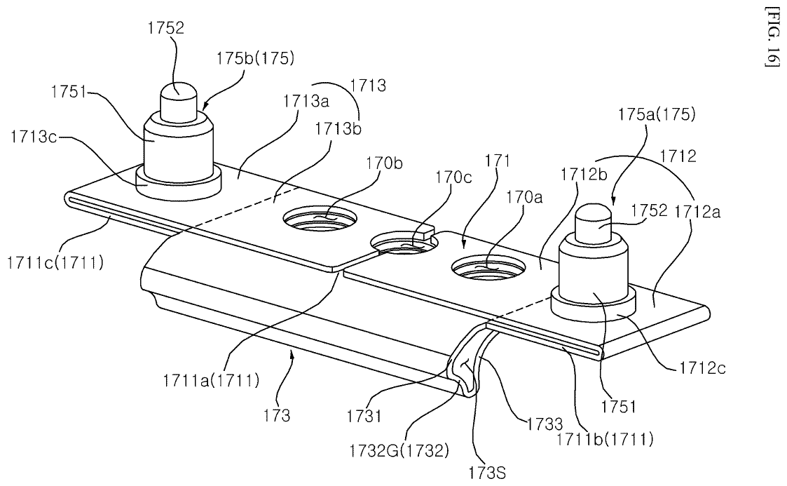

Referring to FIG. 13, the base 171, 172 may include a first side S1 and a second side S2 located in the opposite side of the first side S1. The contact part 174 may be bent while extending in a rearward direction from either the first side S1 or the second side S2. The contact part 174 may be bent while extending in a rearward direction from the first side S1 (see FIG. 8). Alternatively, the contact part 174 may be bent while extending in a rearward direction from the second side S2 (see FIG. 16). In this case, when the base 171, 172 is coupled to the first recessed portion 160a, the second side S2 of the base 171, 172 may mean the lower side of the base 171, 172. When the base 171, 172 is coupled to the fourth recessed portion (not shown), the second side S2 of the base 171, 172 may mean the upper side of the base 171, 172. When the base 171, 172 is coupled to the second recessed portion 160b, the second side S2 of the base 171, 172 may mean the right side of the base 171, 172. When the base 171, 172 is coupled to the third recessed portion 160c, the second side S2 of the base 171, 172 may mean the left side of the base 171, 172.

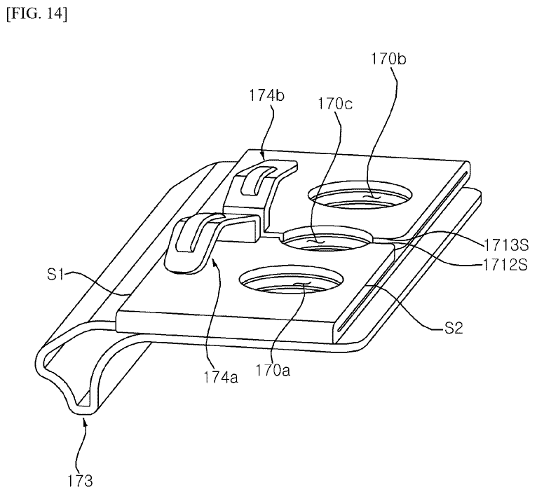

Referring to FIG. 14, the first side part 1712 may include a left side 1712S. The second side part 1713 may include a right side 1713S. When the first side part 1712 and the second side part 1713 are folded, the left side 1712S and the right side 1713S may face each other. The first contact part 174a may extend from the left side 1712S of the first side part 1712 while being bent in a rearward direction. The second contact part 174b may extend from the right side 1713S of the second side part 1713 while being bent in a rearward direction. At this time, the direction in which the first contact part 174a is bent and the direction in which the second contact part 174b is bent may be opposite to each other.

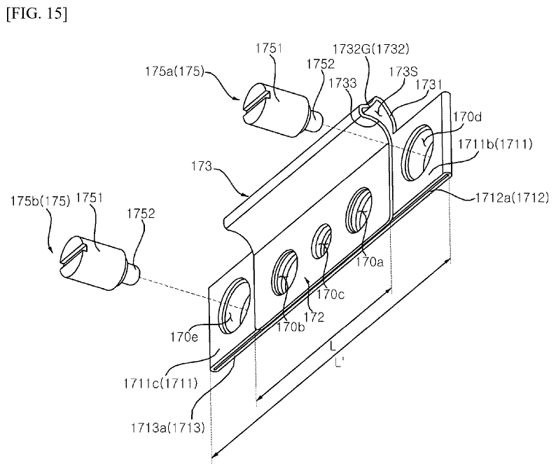

Referring to FIGS. 15 and 16, the holder 170 may include a base 171, 172. The base 171, 172 may be extended long. The base 171, 172 may be coupled to the body 161. The base 171, 172 may include a second base 172 that is in contact with and coupled to the first body 161a. The base 171, 172 may include a first base 171 that faces the first base 171 and is coupled to the first body 161a. The second base 172 may be disposed between the first base 171 and the first body 161a. The first base 171 may be opposite to the first body 161a with respect to the second base 172. The first base 171 and the second base 172 may be provided as a flat plate. The second base 172 may be formed in a plate shape corresponding to the first body 161a.

The first base 171 may include a center part 1711. The center part 1711 may include a first area 1711d that comes into contact with the second base 172. The first area 1711d may be formed in a plate shape corresponding to the second base 172. The length L (see FIG. 15) of the first area 1711d in the longitudinal direction of the base 171, 172 may be formed to be the same as the length L (see FIG. 15) of the second base 172 in a corresponding direction.

The center part 1711 may include a second area 1711e. The second area 1711e may extend from the first area 1711d along the longitudinal direction of the base 171, 172. The second area 1711e may not overlap with the second base 172 in the front-rear direction FR. The second area 1711e may not overlap with the first body 161a in the front-rear direction FR. The second area 1711e may overlap with the second body 161b in the front-rear direction FR.

The center part 1711 may include a third area 1711f. The third area 1711f may extend from the first area 1711d along the longitudinal direction of the base 171, 172. The third area 1711f may be disposed on the opposite side of the second area 1711e with respect to the first area 1711d. The third area 1711f may not overlap with the second base 172 in the front-rear direction FR. The third area 1711f may not overlap with the first body 161a in the front-rear direction FR. The third area 1711f may overlap with the second body 161b in the front-rear direction FR. The center part 1711 may be extended longer than the second base 172. The length L′ (see FIG. 15) of the center part 1711 may be greater than the length L (see FIG. 15) of the second base 172.

The first base 171 may include the first side part 1712. The first side part 1712 may extend from one side surface of the center part 1711 along the longitudinal direction of the base 171, 172. The first side part 1712 may be folded from one side surface of the center part 1711 and in contact with the rear surface of the center part 1711.

The first side part 1712 may include a fourth area 1712d. The fourth area 1712d may extend from the second area 1711e in the longitudinal direction of the base 171, 172. The fourth area 1712d may be folded in a rearward direction from the distal end of the second area 1711e. The fourth area 1712d may be folded and in contact with the rear surface of the second area 1711e. The fourth area 1712d may be formed in a plate shape corresponding to the second area 1711e. The length of the base 171, 172 of the fourth area 1712d in the longitudinal direction may be formed to be the same as the length of the second area 1711e in a corresponding direction.

The first side part 1712 may include a fifth area 1712e. The fifth area 1712e may extend from the fourth area 1712d. The fifth area 1712e may be in contact with the first area 1711d of the center part 1711. The fifth area 1712e may be in contact with at least a part of the first area 1711d of the center part 1711. The length of the base 171, 172 of the fifth area 1712e in the longitudinal direction may be smaller than the length L of the first area 1711d.

The first base 171 may include a second side part 1713. The second side part 1713 may extend from the other side surface of the center part 1711 along the longitudinal direction of the base 171, 172. The second side part 1713 may be disposed on the opposite side with respect to the center part 1711. The second side part 1713 may be folded from the other side surface of the center part 1711 and may come into contact with the rear surface of the center part 1711.

The second side part 1713 may include a sixth area 1713d. The sixth area 1713d may extend in the longitudinal direction of the base 171, 172 from the third area 1711f. The sixth area 1713d may be folded in a rearward direction from the distal end of the third area 1711f. The sixth area 1713d may be folded to come into contact with the rear surface of the third area 1711f. The sixth area 1713d may be formed in a plate shape corresponding to the third area 1711f. The length of the sixth area 1713d in the longitudinal direction of the base 171, 172 may be formed to be the same as the length of the third area 1711f in a corresponding direction.

The second side part 1713 may include a seventh area 1713e. The seventh area 1713e may extend from the sixth area 1713d. The seventh area 1713e may be in contact with the first area 1711d of the center part 1711. The seventh area 1713e may be in contact with at least a part of the first area 1711d of the center part 1711. The length of the base 171, 172 of the seventh area 1713e in the longitudinal direction may be smaller than the length L of the first area 1711d. The seventh area 1713e may face the fifth area 1712e on the base 1711. The sum of the lengths of the seventh area 1713e and the fifth area 1712e may correspond to the length L of the first area 1711d.

The first guide hole 170a may be formed by penetrating the second base 172, the first area 1711d of the center part 1711, and the fifth area 1712e of the first side part 1712. The first protruding part 163a may be inserted into the first guide hole 170a.

The second guide hole 170b may be formed by penetrating the second base 172, the first area 1711d of the center part 1711, and the seventh area 1712e of the second side part 1713. The second protruding part 163b may be inserted into the second guide hole 170b.

The coupling hole 170c may be formed by penetrating the first area 1711d of the center part 1711 of the second base 172, the fifth area 1712e of the first side part 1712, and the seventh area 1712e of the second side part 1713. The hole formed in the fifth area 1712e of the first side part 1712 and the hole formed in the seventh area 1712e of the second side part 1713 may have a semicircular shape. The hole formed in the fifth area 1712e of the first side part 1712 and the hole formed in the seventh area 1712e of the second side part 1713 may be combined to form a circular shape. A fastening member F such as a screw may penetrate the coupling hole 170c, and may be inserted into the hole 162 through the coupling hole 170c and screw-fastened to the tapping part 164 (see FIG. 11). Thus, the holder 170 may be fixed to the recessed portion 160.

Among the bases 171, 172, a portion that overlaps with the first body 161a in the front-rear direction FR may be referred to as a central area, and a portion that does not overlap with the first body 161a in the front-rear direction FR may be referred to as a side area. The central area may be composed of the second base 172, the first area 1711d of the center part 1711, the fifth area 1712e of the first side part 1712, and the seventh area 1713e of the second side part 1713. The side area may include a first side area located on one side of the central area, and a second side area located on the other side of the central area. The first side area may be composed of the second area 1711e of the center part 1711 and the fourth area 1712d of the first side part 1712. The second side area may be composed of the third area 1711f of the center part 1711 and the sixth area 1713d of the second side part 1713.

A first through hole 170e may be formed in the first side area. The first through hole 170e may be formed by penetrating the second area 1711e and the fourth area 1712d in the front-rear direction FR. A second through hole 170f may be formed in the second side area. The second through hole 170f may be formed by penetrating the third area 1711f and the sixth area 1713d in the front-rear direction FR.

A first tapping part 1712f may be formed along the periphery of the first through hole 170e. The first tapping part 1712f may protrude in a rearward direction from the periphery of the first through hole 170e formed in the fourth area 1712d. A first contact part 175a described later may be coupled to the first tapping part 1712f. The first contact part 175a may be rotated to be coupled to the first tapping part 1712f. For example, a screw thread may be formed on the inner circumferential surface of the first tapping part 1712f. The first through hole 170e formed in the second area 1711e may be burred.

A second tapping part 1713f may be formed along the periphery of the second through hole 170f. The second tapping part 1713f may protrude in a rearward direction from the periphery of the second through hole 170f formed in the sixth area 1713d. A second contact part 175b described later may be coupled to the second tapping part 1713f. The second contact part 175b may be rotated to be coupled to the second tapping part 1713f. The second through hole 170f formed in the third area 1711f may be burred.

The holder 170 may include a bending part 173. The bending part 173 may be extended in the longitudinal direction of the base 171, 172. The length L of the bending part 173 may be equal to or smaller than the length of the second base 172. The length L of the bending part 173 may be equal to or smaller than the length of the first area 1711d of the center part 1711. The bending part 173 may be fixed or coupled to one side of the base 171, 172. The bending part 173 may be bent multiple times. One end of the bending part 173 may be fixed or coupled to the first area 1711d of the first base 171. The other end of the bending part 173 may be fixed or coupled to the second base 172. At this time, one end and the other end of the bending part 173 may be adjacent or neighboring to each other. The inner surface of the bending part 173 may define a boundary of the space 173S. The space 173S may be extended in the longitudinal direction of the bending part 173.

The bending part 173 may include a first tension portion 1731. The first tension portion 1731 may be connected to the first area 1711d of the center part 1711 of the first base 171. The bending part 173 may include a second tension portion 1733. The second tension portion 1733 may be connected to the second base 172. The bending part 173 may include a seating portion 1732 connecting the first tension portion 1731 and the second tension portion 1733. The seating portion 1732 may extend in a forward direction while rolling from the first tension portion 1731. The seating portion 1732 may include a groove 1732G that is recessed toward the bases 171, 172. The coupling portion 153 of the back cover 150 may be seated on the groove 1732G. The bending part 173 is substantially the same as the bending part 173 illustrated in FIGS. 8 and 9, and may be understood by referring to the descriptions described in FIGS. 8 and 9.

The first base 171, the second base 172 and the bending part 173 may be formed as one body.

The holder 170 may include a contact part 175. The contact part 175 may be inserted into the through hole 170e, 170f and may protrude toward the rear of the base 171, 172. The contact part 175 may be inserted from the front F toward the rear R and may protrude toward the rear of the base 171, 172. The contact part 175 may include a first contact part 175a inserted into the first through hole 170e and a second contact part 175b inserted into the second through hole 170f. The first contact part 175a and the second contact part 175b may have the same structure. The contact part 175 may be referred to as a plunger 175. The first contact part 175a and the second contact part 175b may be referred to as a first plunger 175a and a second plunger 175b.

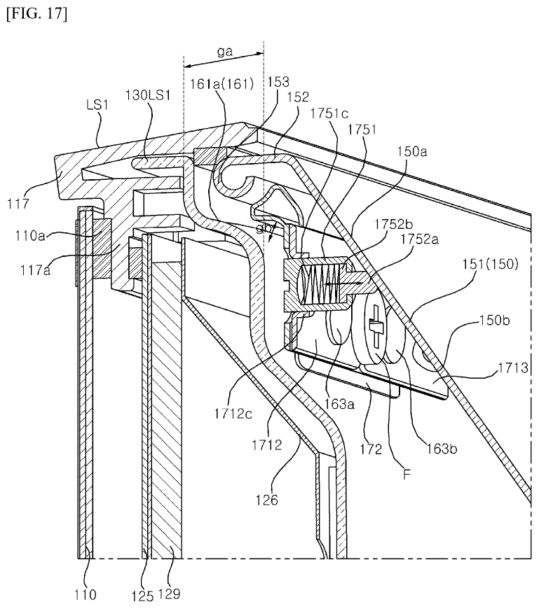

Referring to FIGS. 16 and 17, the contact part 175 may include a housing 1751. The housing 1751 may be inserted into the through hole 170e, 170f. The housing 1751 may be formed in a cylindrical shape with a space 1751S formed therein. The housing 1751 may be rotated and fastened to the tapping part 1712f, 1713f. The housing 1751 may protrude toward the rear of the base 171, 172. A hole 1751H may be formed on one side surface of the housing 1751.

The contact part 175 may include a rod 1752. The rod 1752 may include a bottom 1752b accommodated in an internal space 1751S of the housing 1751 and a head 1752a extending from the bottom 1752b. The head 1752a may be inserted into the hole 1751H and may protrude to the outside of the housing 1751. The head 1752a may be in contact with the inner surface 150b of the back cover 150. The diameter of the hole 1751H may be formed to be the same as the diameter of the head 1751a. The diameter of the bottom 1752b may be larger than the diameter of the hole 1751H. The bottom 1752b may span one surface of the housing 1751 in which the hole 1751H is formed. Through this, the rod 1752 may be prevented from being separated from the housing 1751. The diameter of the bottom 1752b may be the same as the inner diameter of the housing 1751.

The contact part 1755 may be formed of a metal material. For example, the housing 1751 and the rod 1752 may be formed of a metal material.

The contact part 1755 may include an elastic member 1752c. For example, the elastic member 1752c may be a spring. The elastic member 1752c may be accommodated in the inner space 1751S of the housing 1751. The elastic member 1752c may support the bottom 1752b. The elastic member 1752c may elastically support the rod 1752.

When the back cover 150 is coupled to the seating portion 1732 of the bending part 173, the cover portion 151 may come into contact with the head 1751a of the rod 1752. At this time, the rod 1752 may be pressed toward the front F by the cover portion 151 due to the elastic deformation of the elastic member 1752c. When the back cover 150 is seated on the seating portion 1732 of the bending part 173 to complete a coupling, the rod 1752 may maintain contact with the inner surface 150b of the cover portion 151 due to the restoring force of the elastic member 1752c. The elastic member 1752c may push the rod 1752 toward the back cover 150, and secure contact stability between the rod 1752 and the inner surface 150b of the back cover 150. Through this, EMI noise may be reduced.

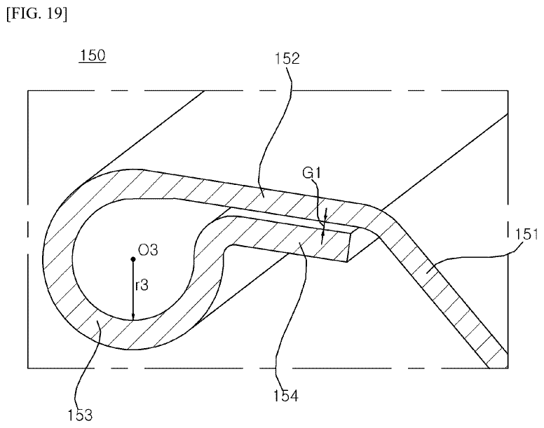

Referring to FIG. 19, the connecting portion 153 of the back cover 150 may be curled while drawing a circle of a third radius r3 with respect to a third center 03 adjacent to the inner surface of the connecting portion 152.

The back cover 150 may include a reinforcing part 154. The reinforcing part 154 may extend from the connecting portion 153 toward the cover portion 151. The reinforcing part 154 may face or be parallel to the inner surface of the connecting portion 152. The reinforcing part 154 may be spaced apart from the inner surface of the connecting portion 152 by a first gap G1 or may come into contact therewith. Accordingly, the rigidity of the back cover 150 against sagging and twisting may be improved.

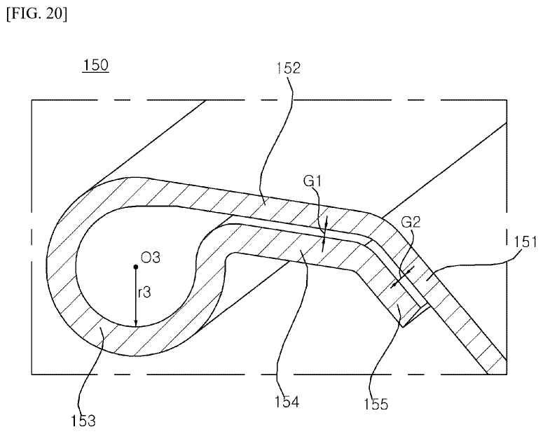

Referring to FIG. 20, the back cover 150 may include a rigid part 155. The rigid part 155 may be bent from the reinforcing part 154. The rigid part 155 may form an obtuse angle with respect to the reinforcing part 154 and may extend from the reinforcing part 154 toward the cover portion 151. The rigid part 155 may face or be parallel to the connecting portion 152 and/or the cover portion 151. The rigid part 155 may be spaced apart from the inner surface of the cover portion 151 by a second gap G2 smaller than the first gap G1 or may be in contact therewith. Accordingly, the rigidity of the back cover 150 against sagging and twisting may be further improved.

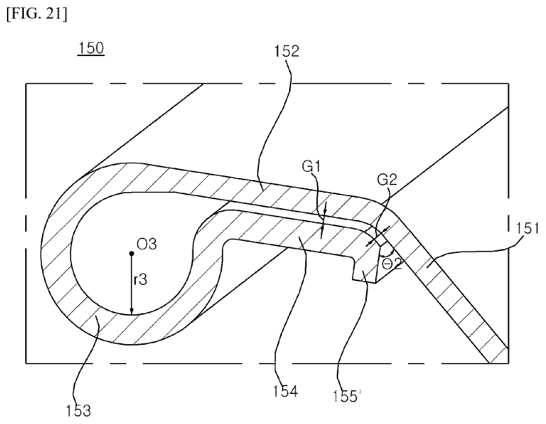

Referring to FIG. 21, a rigid part 155′ may be bent from the reinforcing part 154. The rigid part 155′ may extend in a direction intersecting with the extension direction of the connecting portion 152 and/or the cover portion 151. The rigid part 155′ may form an acute angle (theta 2) with respect to the inner surface of the cover portion 151 and may extend from the reinforcing part 154. The rigid part 155′ may be adjacent to the inner surface of the cover portion 151. A portion where the reinforcing part 154 and the rigid part 155′ are connected may be spaced apart from the inner surface of the cover portion 151 by a second gap G2 smaller than the first gap G1 or may be in contact therewith. Accordingly, the rigidity of the back cover 150 against sagging and twisting may be further improved.

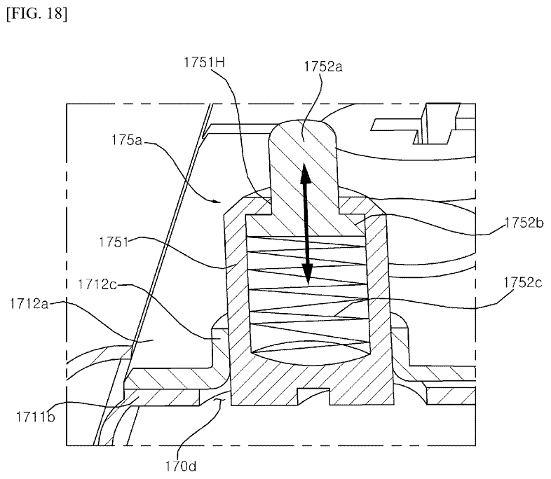

Referring to FIGS. 1 to 21, a display device according to an aspect of the present disclosure may include: a display panel 110; a frame 130 disposed at a rear of the display panel 110; a holder 170 which is disposed at a rear of the frame 130 and which is coupled to the frame 130; and a back cover 150 which is coupled to the holder 170 and which covers the rear of the frame 130, wherein the holder 170 may include: a base 171, 172 which is in contact with the frame 130 and which is coupled to the frame 130; and a contact part 174, 175 which is coupled to the base 171, 172, which protrudes toward a rear of the base 171, 172, and which is in contact with an inner surface 150b of the back cover 150.

According to another aspect of the present disclosure, the contact part 174, 175 may include: a support portion 1741 extending in a direction perpendicular to a longitudinal direction of the base 171, 172 from one side of the base 171, 172; and an elastic portion 1742 which is bent from the support portion 1741 and which faces the base 171, 172, and which has a portion that comes in contact with the inner surface of the back cover 150, wherein the elastic portion 1742 may be spaced rearward from a rear surface of the base 171, 172.

According to another aspect of the present disclosure, the elastic portion 1742 may include: a first part 1742a which is bent from the support portion 1741 and extends toward the back cover 150; and a second part 1742b which is bent from the first part 1742a and extends toward the base 171, 172, wherein the first part 1742a may be in contact with the inner surface of the back cover 150.

According to another aspect of the present disclosure, the support portion 1741 and the first part 1742a may form a first angle (theta 1), and the first part 1742a and the second part 1742b may form a second angle (theta 2), wherein the second angle (theta 2) may be greater than the first angle (theta 1).

According to another aspect of the present disclosure, the back cover 150 may include: a cover portion 151 forming a rear surface of the back cover 150; a coupling portion 153 which is curled from a distal end of the back cover 150 toward the inner surface of the back cover 150; and a connecting portion 152 which is bent from the cover portion 151, which extends toward the frame 130, and which is connected to the coupling portion 153, wherein the first part 1742a may be formed parallel to the cover portion 151.

According to another aspect of the present disclosure, the contact part 174, 175 may include a protrusion 1743 that protrudes in a rearward direction from the elastic portion 1742, and that is in contact with the inner surface of the back cover 150.

According to another aspect of the present disclosure, the base 171, 172 may include: a first base 171, 172; and a second base 171, 172 which is disposed in front of the first base 171, 172, and which is in contact with the frame 130, wherein the first base 171, 172 may include: a center part 1711 facing the second base 171, 172; a first side part 1712 which extends from one side of the center part 1711, and which is folded to face a rear surface of the center part 1711; and a second side part 1713 which extends from the other side located opposite the one side of the center part 1711, and which is folded to face the rear surface of the center part 1711, wherein the contact part 174, 175 may extend in a rearward direction from at least one of the first side part 1712 and the second side part 1713.

According to another aspect of the present disclosure, the holder 170 may include a bending part 173 which is bent in a forward direction from the base 171, 172, which is disposed adjacent to one side of the frame 130, and which is coupled with a coupling portion 153 formed at a distal end of the back cover 150, wherein the bending part 173 may include: a first tension portion 1731 which extends from the base 171, 172 and which forms one end of the bending part 173; a second tension portion 1733 which extends from the base 171, 172 and which forms the other end of the bending part 173; and a seating portion 1732 which connects the first tension portion 1731 and the second tension portion 1733, and which is recessed toward the base 171, 172, wherein the back cover 150 may include a coupling portion 153 which is formed at a distal end of the back cover 150, and which is curled from the distal end of the back cover 150 toward the inner surface 150b of the back cover 150 and which is seated on the seating portion 1732.

According to another aspect of the present disclosure, the seating portion 1732 may be formed to be curved, and a curvature of the coupling portion 153 may be formed to be the same as a curvature of the seating portion 1732.

According to another aspect of the present disclosure, the frame 130 may include a recessed portion 160 which is disposed adjacent to an edge of the frame 130, which is recessed in a rearward direction from a front surface of the frame 130, and which is coupled to the base 171, 172, wherein the recessed portion 160 may include: a body 161 with which the base 171, 172 is in contact; a protruding part 163 which protrudes in the rearward direction from the body 161; and a hole 162 which is spaced apart from the protruding part 163 and penetrates the body 161 in a front-rear direction, wherein the base 171, 172 may include: a guide hole 170a, 170b into which the protruding part 163 is inserted; and a coupling hole 170c which is spaced apart from the guide hole 170a, 170b, and which is aligned with the hole 162.

According to another aspect of the present disclosure, the base 171, 172 may include: a central area which overlaps with the body 161, and in which the guide hole 170a, 170b and the coupling hole 170c are formed; and a side area which extends from the central area, and which is not overlapped with the body 161, wherein the contact part 174, 175 may penetrate the side area and protrudes toward a rear of the base 171, 172.

According to another aspect of the present disclosure, the contact part 174, 175 may include: a housing 1751 which has an internal space formed therein, which has a hole 1751H formed in one surface, and which is coupled by penetrating the side area; and a rod 1752 which is inserted into the hole 1751H of the housing 1751, and which comes into contact with the inner surface 150b of the back cover 150.

According to another aspect of the present disclosure, the contact part 174, 175 may include an elastic member 1752c that is disposed in the internal space of the housing 1751, and that supports the rod 1752.

According to another aspect of the present disclosure, the base 171, 172 may include: a through hole 170e, 170f which is formed in the side area, and through which the contact part 174, 175 penetrates to be coupled; and a tapping part 1712f, 1713f which extends from a periphery of the through hole 170e, 170f, and which is in contact with the housing 1751.

According to another aspect of the present disclosure, the frame 130, the holder 170, and the back cover 150 may be formed of a conductive material, wherein a painted layer covering the conductive material may be formed on an outer surface 150a of the back cover 150, and in which the conductive material is exposed on the inner surface 150b of the back cover 150.

Certain embodiments or other embodiments of the invention described above are not mutually exclusive or distinct from each other. Any or all elements of the embodiments of the invention described above may be combined or combined with each other in configuration or function.

For example, a configuration “A” described in one embodiment of the invention and the drawings and a configuration “B” described in another embodiment of the invention and the drawings may be combined with each other. Namely, although the combination between the configurations is not directly described, the combination is possible except in the case where it is described that the combination is impossible.

Although embodiments have been described with reference to a number of illustrative embodiments thereof, it should be understood that numerous other modifications and embodiments may be devised by those skilled in the art that will fall within the scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

1. A display device comprising:
a display panel;
a frame disposed at a rear of the display panel;
a holder which is disposed at a rear of the frame and which is coupled to the frame; and
a back cover which is coupled to the holder and which covers the rear of the frame,
wherein the holder comprises:
a base which is in contact with the frame and which is coupled to the frame; and
a contact part which is coupled to the base, which protrudes toward a rear of the base, and which is in contact with an inner surface of the back cover.

2. The display device of claim 1, wherein the contact part comprises:
a support portion extending in a direction perpendicular to a longitudinal direction of the base from one side of the base; and
an elastic portion which is bent from the support portion and which faces the base, and which has a portion that comes in contact with the inner surface of the back cover,
wherein the elastic portion is spaced rearward from a rear surface of the base.

3. The display device of claim 2, wherein the elastic portion comprises:
a first part which is bent from the support portion and extends toward the back cover; and
a second part which is bent from the first part and extends toward the base,
wherein the first part is in contact with the inner surface of the back cover.

4. The display device of claim 3, wherein the support portion and the first part form a first angle, and
the first part and the second part form a second angle,
wherein the second angle is greater than the first angle.

5. The display device of claim 3, wherein the back cover comprises:
a cover portion forming a rear surface of the back cover;
a coupling portion which is curled from a distal end of the back cover toward the inner surface of the back cover; and
a connecting portion which is bent from the cover portion, which extends toward the frame, and which is connected to the coupling portion,
wherein the first part is formed parallel to the cover portion.

6. The display device of claim 3, wherein the contact part comprises a protrusion that protrudes in a rearward direction from the elastic portion, and that is in contact with the inner surface of the back cover.

7. The display device of claim 1, wherein the base comprises:
a first base; and
a second base which is disposed in front of the first base, and which is in contact with the frame,
wherein the first base comprises:
a center part facing the second base;
a first side part which extends from one side of the center part, and which is folded to face a rear surface of the center part; and
a second side part which extends from the other side located opposite the one side of the center part, and which is folded to face the rear surface of the center part,
wherein the contact part extends in a rearward direction from at least one of the first side part and the second side part.

8. The display device of claim 1, wherein the holder comprises a bending part which is bent in a forward direction from the base, which is disposed adjacent to one side of the frame, and which is coupled with a coupling portion formed at a distal end of the back cover,
wherein the bending part comprises:
a first tension portion which extends from the base and which forms one end of the bending part;
a second tension portion which extends from the base and which forms the other end of the bending part; and
a seating portion which connects the first tension portion and the second tension portion, and which is recessed toward the base,
wherein the back cover comprises a coupling portion which is formed at a distal end of the back cover, and which is curled from the distal end of the back cover toward the inner surface of the back cover and which is seated on the seating portion.

9. The display device of claim 8, wherein the seating portion is formed to be curved, and
a curvature of the coupling portion is formed to be the same as a curvature of the seating portion.

10. The display device of claim 1, wherein the frame comprises a recessed portion which is disposed adjacent to an edge of the frame, which is recessed in a rearward direction from a front surface of the frame, and which is coupled to the base,
wherein the recessed portion comprises:
a body with which the base is in contact;
a protruding part which protrudes in the rearward direction from the body; and
a hole which is spaced apart from the protruding part and which penetrates the body in a front-rear direction,
wherein the base comprises:
a guide hole into which the protruding part is inserted; and
a coupling hole which is spaced apart from the guide hole, and which is aligned with the hole.

11. The display device of claim 10, wherein the base comprises:
a central area which overlaps with the body, and in which the guide hole and the coupling hole are formed; and
a side area which extends from the central area, and which is not overlapped with the body,
wherein the contact part penetrates the side area and protrudes toward a rear of the base.

12. The display device of claim 11, wherein the contact part comprises:
a housing which has an internal space formed therein, which has a hole formed in one surface, and which is coupled by penetrating the side area; and
a rod which is inserted into the hole of the housing, and which comes into contact with the inner surface of the back cover.

13. The display device of claim 12, wherein the contact part comprises an elastic member that is disposed in the internal space of the housing, and that supports the rod.

14. The display device of claim 12, wherein the base comprises:
a through hole which is formed in the side area, and through which the contact part penetrates to be coupled; and
a tapping part which extends from a periphery of the through hole, and which is in contact with the housing.

15. The display device of claim 1, wherein the frame, the holder, and the back cover are formed of a conductive material,
wherein a painted layer covering the conductive material is formed on an outer surface of the back cover, and
wherein the conductive material is exposed on the inner surface of the back cover.
